(19) United States
(12) Patent Application Publication
(10) Pub. No.: US 2026/0114004 A1
(43) Pub. Date: Apr. 23, 2026

(54) METHOD OF MANUFACTURING SEMICONDUCTOR STRUCTURE

(71) Applicant: NANYA TECHNOLOGY CORPORATION, New Taipei City (TW)

(72) Inventors: Ying-Cheng CHUANG, New Taipei City (TW); Chung-Lin HUANG, New Taipei City (TW)

(21) Appl. No.: 18/922,603

(22) Filed: Oct. 22, 2024

(51) Int. Cl. H01L 29/40

(52) U.S. Cl. CPC H10D 64/01

(57) ABSTRACT

A method of manufacturing a semiconductor structure includes the following steps. A substrate is received with a top electrode of an embedded capacitor exposed from the substrate. An oxide layer is formed on the substrate. A patterned sacrificial layer is formed on the oxide layer and a portion of the oxide layer is exposed. A metal layer is formed to cover the portion of the oxide layer. A patterned dielectric layer is formed on the metal layer. A spacer is formed on a sidewall of the patterned dielectric layer. The metal layer is patterned by using the spacer and the patterned dielectric layer as a mask to form a gap. The gap is filled with a filler. The patterned sacrificial layer is removed to expose the top electrode of the embedded capacitor. A gate structure is formed on the top electrode of the embedded capacitor.

### BACKGROUND

### Field of Invention

The present disclosure relates to a method of manufacturing a semiconductor structure.

### Description of Related Art

Semiconductor devices are essential for many modern applications. With the advancement of electronic technology, semiconductor devices are becoming smaller in size while providing greater functionality and including greater amounts of integrated circuitry. Due to the miniaturized scale of semiconductor devices, various types and dimensions of semiconductor devices providing different functionalities are integrated and packaged into a single module. Furthermore, numerous manufacturing operations are implemented for integration of various types of semiconductor devices.

However, the manufacturing and integration of semiconductor devices involve many complicated steps and operations. Integration in semiconductor devices becomes increasingly complicated. An increase in complexity of manufacturing and integration of the semiconductor device may cause deficiencies, such as an increase in parasitic capacitance between adjacent interconnect structures. Accordingly, there is a continuous need to improve the manufacturing process of semiconductor devices so that the deficiencies can be addressed.

### SUMMARY

One aspect of the present disclosure is to provide a method of manufacturing a semiconductor structure. The method includes the following steps. A substrate is received with a top electrode of an embedded capacitor exposed from the substrate. An oxide layer is formed on the substrate. A patterned sacrificial layer is formed on the oxide layer and a portion of the oxide layer is exposed. A metal layer is formed to cover the portion of the oxide layer. A patterned dielectric layer is formed on the metal layer, in which a top surface of the patterned dielectric layer is leveled with a top surface of the patterned sacrificial layer. A spacer is formed on a sidewall of the patterned dielectric layer. The metal layer is patterned by using the spacer and the patterned dielectric layer as a mask to form a gap. The gap is filled with a filler. The patterned sacrificial layer is removed to expose the top electrode of the embedded capacitor. A gate structure is formed on the top electrode of the embedded capacitor.

In one or more embodiments, the patterned sacrificial layer is substantially aligned with the top electrode of the embedded capacitor.

In one or more embodiments, forming the patterned sacrificial layer includes: forming a sacrificial layer cover the oxide layer; forming a patterned resist layer on the sacrificial layer; and patterning the sacrificial layer by using the patterned resist layer as a mask to form the patterned sacrificial layer.

In one or more embodiments, forming the metal layer cover the portion of the oxide layer includes: depositing a metal material covering the portion of the oxide layer and the patterned sacrificial layer; etching back the metal material; and recessing the metal material to form the metal layer, wherein a height of the metal layer is lower than a height of the patterned sacrificial layer.

In one or more embodiments, forming the patterned dielectric layer on the metal layer includes: depositing an oxide material layer covering the metal layer and the patterned sacrificial layer; etching back and recessing the oxide material layer so that a top surface of the oxide material layer is lower than the top surface of the patterned sacrificial layer; depositing a nitride material layer covering the oxide material layer and the patterned sacrificial layer; etching back the nitride material layer so that a top surface of the nitride material layer is leveled with the top surface of the patterned sacrificial layer; depositing a carbon layer covering the nitride material layer and the patterned sacrificial layer; forming a patterned resist layer on the carbon layer; patterning the carbon layer, the nitride material layer, and the oxide material layer by using the patterned resist layer as a mask; and removing the patterned resist layer and the patterned carbon layer to form the patterned dielectric layer.

In one or more embodiments, forming the patterned dielectric layer on the metal layer includes: forming the patterned dielectric layer between the patterned sacrificial layer, in which the sidewall of the patterned dielectric layer and a sidewall of the closest patterned sacrificial layer are spaced apart from each other.

In one or more embodiments, the spacer on the patterned dielectric layer and the spacer on the closest patterned sacrificial layer are spaced apart from each other.

In one or more embodiments, the gate structure includes a gate dielectric layer and a gate electrode disposed on the gate dielectric layer, and the gate electrode includes indium gallium zinc oxide.

In one or more embodiments, the method of manufacturing the semiconductor structure further includes forming a landing pad on the gate structure.

Another aspect of the present disclosure is to provide a method of manufacturing a semiconductor structure. The method includes the following steps. A substrate is received with a plurality of top electrodes of a plurality of embedded capacitors exposed from the substrate. A plurality of dummy pillars is formed on the plurality of top electrodes of the plurality of embedded capacitors. A metal layer is deposited on the substrate, in which a plurality of lower portions of the plurality of dummy pillars is surrounded by the metal layer. A patterned dielectric layer is formed on the metal layer and between two adjacent dummy pillars. A spacer is formed on a sidewall of the patterned dielectric layer and an upper portion of each of the plurality of dummy pillars. The metal layer is patterned by using the spacer and the patterned dielectric layer as a mask to form a gap. The gap is filled with a filler. The plurality of dummy pillars is removed to expose the plurality of top electrodes of the plurality of embedded capacitors. A plurality of gate structures is formed on the plurality of top electrodes of the plurality of embedded capacitors.

In one or more embodiments, the method of manufacturing the semiconductor structure further includes forming an oxide layer between the substrate and the plurality of dummy pillars.

In one or more embodiments, the plurality of dummy pillars is arranged at intervals.

In one or more embodiments, each of the plurality of dummy pillars has a round profile in a top view.

In one or more embodiments, a vertical projection of each of the plurality of dummy pillar on the substrate substantially overlaps a vertical projection of each of the plurality of top electrodes on the substrate.

In one or more embodiments, a thickness of each of the plurality of dummy pillars is larger than a thickness of the metal layer.

In one or more embodiments, a width of the patterned dielectric layer is substantially the same as a diameter of each of the plurality of dummy pillars in a top view.

In one or more embodiments, an edge of the patterned dielectric layer is surrounded by the spacer in a top view.

In one or more embodiments, the filler includes an oxide.

In one or more embodiments, each of the plurality of gate structures includes a gate dielectric layer and a gate electrode disposed on the gate dielectric layer, and the gate electrode includes indium gallium zinc oxide.

In one or more embodiments, the method of manufacturing the semiconductor structure further includes forming a plurality of landing pads on the plurality of gate structures.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1A, 2A, 3A, 4A, 5A, 6A, 7A, 8A, 9A, 10A, 11A, 12A, 13A, 14A, 15A, 16A, and FIG. 17A illustrate cross-sectional views of an exemplary semiconductor structure during various fabrication stages, in accordance with some embodiments.

FIGS. 1B, 2B, 3B, 4B, 5B, 6B, 7B, 8B, 9B, 10B, 11B, 12B, 13B, 14B, 15B, 16B, and FIG. 17B are top views of FIGS. 1A, 2A, 3A, 4A, 5A, 6A, 7A, 8A, 9A, 10A, 11A, 12A, 13A, 14A, 15A, 16A, and FIG. 17A, respectively.

FIG. 18 illustrates a perspective view of a semiconductor structure, in portion, during various fabrication stages, in accordance with some embodiments.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless otherwise defined, all terms (including technical and scientific terms) used herein have the same meanings as those commonly understood by a person having ordinary skill in the art to which the embodiments of the present disclosure belong. It should be understood that terms, such as those defined in commonly used dictionaries, should be interpreted as having a meaning that is consistent with their meaning in the context of the relevant art and the present disclosure, and should not be interpreted in an idealized or overly formal sense unless expressly so defined herein.

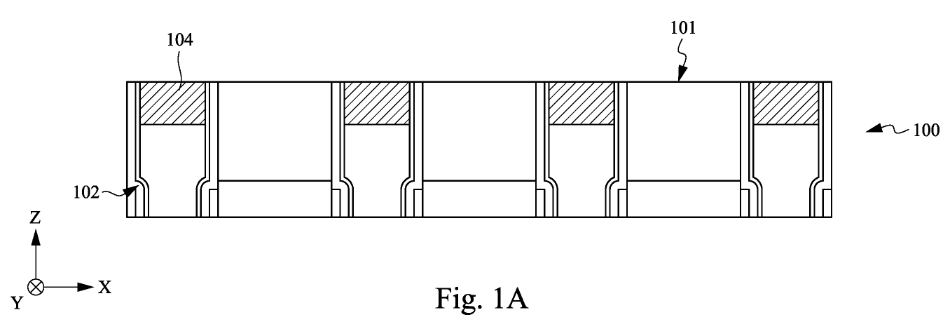

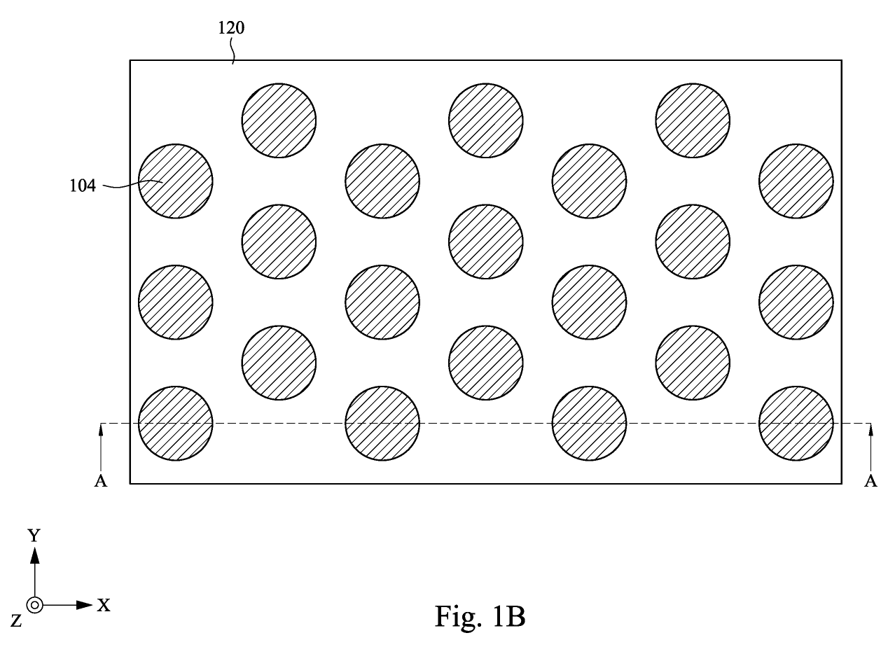

FIGS. 1A, 1B, 2A, 2B, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, and FIG. 17B illustrate various views of intermediate stages in the formation of a semiconductor structure in accordance with some embodiments of the present disclosure.

First, referring to FIGS. 1A and 1B, a substrate 100 is received to serve as a base for forming devices, components, or circuits. In some embodiments, the substrate 100 may be a semiconductor substrate. The substrate 100 may include silicon (Si), gallium (Ga), gallium arsenide (GaAs), gallium nitride (GaN), strained silicon, silicon-germanium (SiGe), silicon carbide (SiC), diamond, epitaxy layer or a combination thereof, but the disclosure is not limited thereto. The substrate 100 may include, consist essentially of, or consist of monocrystalline silicon, and may be referred to as a semiconductor substrate, or as a portion of a semiconductor substrate. In some embodiments, a well region (not shown) may be formed in the substrate 100. The well region may be neutral, or may be an n-type or p-type doped region, depending on the conductivity type of the transistor structure to be formed thereafter. An isolation structure (not shown), such as a shallow trench isolation (hereinafter abbreviated as STI) structure, is formed in the substrate 100 for defining at least an active region (not shown).

The terms “semiconductive substrate,” “semiconductor construction” and “semiconductor substrate” mean any construction including semiconductive material, including, but not limited to, bulk semiconductive materials such as a semiconductive wafer (either alone or in assemblies comprising other materials), and semiconductive material regions (either alone or in assemblies comprising other materials). The term “substrate” refers to any supporting structure, including, but not limited to, the semiconductive substrates described above. Although the substrate 100 in this embodiment is shown to be homogenous, the substrate may include numerous materials in some embodiments. For instance, the substrate 100 may correspond to a semiconductor substrate containing one or more materials associated with integrated circuit fabrication. In such embodiments, such materials may correspond to one or more of refractory metal materials, barrier materials, diffusion materials, insulator materials, etc.

FIG. 1A is a schematic cross-sectional view along line A-A in FIG. 1B. As shown in FIGS. 1A and 1B, a top electrode 104 of an embedded capacitor 102 is exposed from the substrate 100. In some embodiment, an upper surface of the top electrode 104 is substantially leveled with the top surface 101 of the substrate 100, as shown in FIG. 1A. It is noted that FIG. 1A merely shows part of the structure of the embedded capacitor 102. It can be understood that the embedded capacitor 102 includes at least the top electrode 104, a bottom electrode (not shown), a dielectric layer (not shown) between the top electrode 104 and the bottom electrode. In some embodiments, the top electrode 104 exposed from a top surface 101 of the substrate 100 has substantially a round profile in a top view, as shown in FIG. 1B. In some embodiment, in FIG. 1B, the top electrodes 104 are spaced in a column in the Y direction and spaced staggered from each other in the X direction. In addition, the number of the embedded capacitors 120 may be multiple.

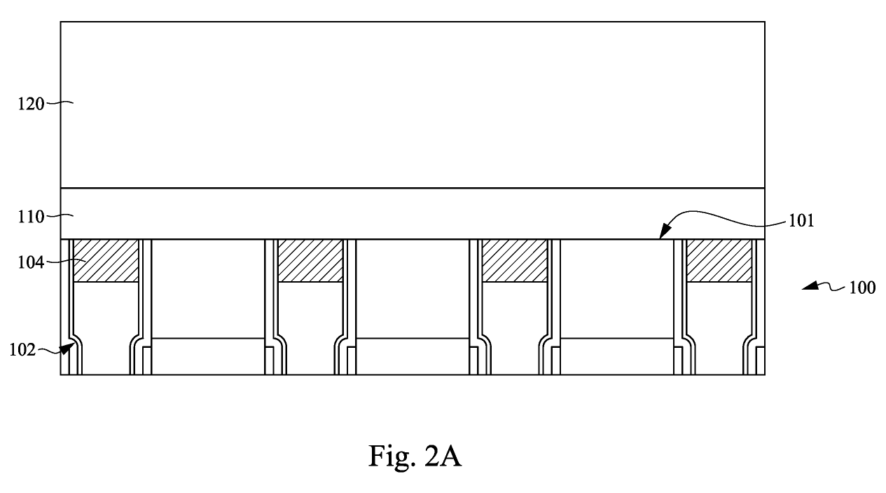

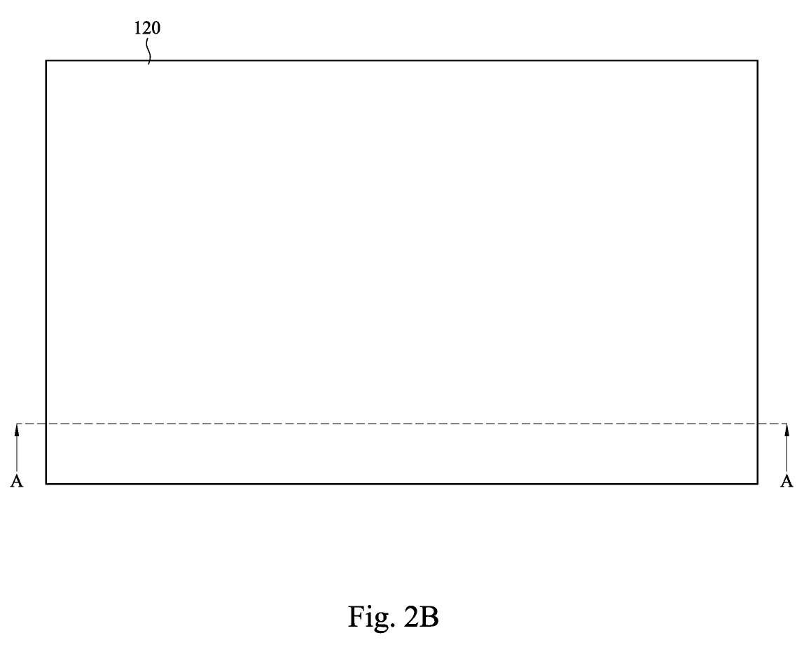

Next, referring to FIGS. 2A and 2B, an oxide layer 110 is formed on the substrate 100. To be specific, the oxide layer 110 completely covers the top surface 101 of the substrate 100. In other words, the oxide layer 110 further covers the top electrodes 104 of the embedded capacitor 102. The oxide layer 110 is formed conformally on the top surface 101 of the substrate 100. In some embodiments, the oxide layer 110 is an insulating oxide layer. The insulating oxide layer is made of any suitable dielectric material, such as silicon oxide, boro-phospho silicate glass (BPSG), or traethylorthosilicate(TEOS), but the present disclosure is not limited to the above material.

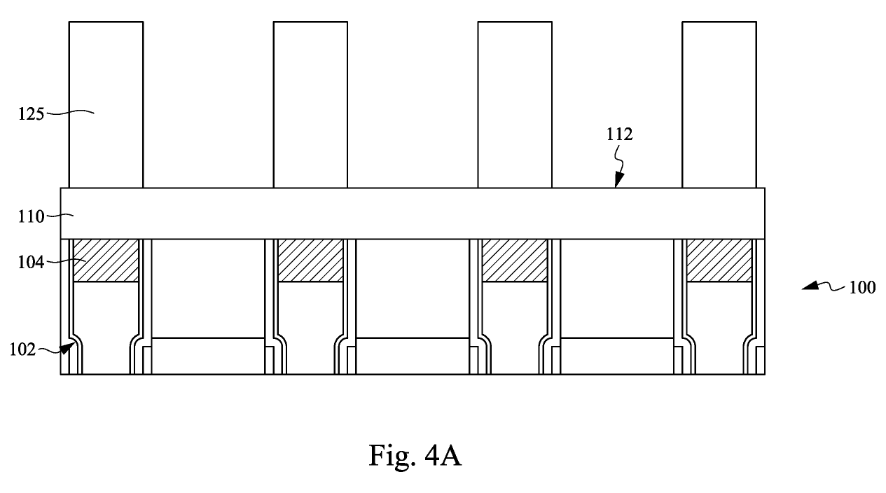

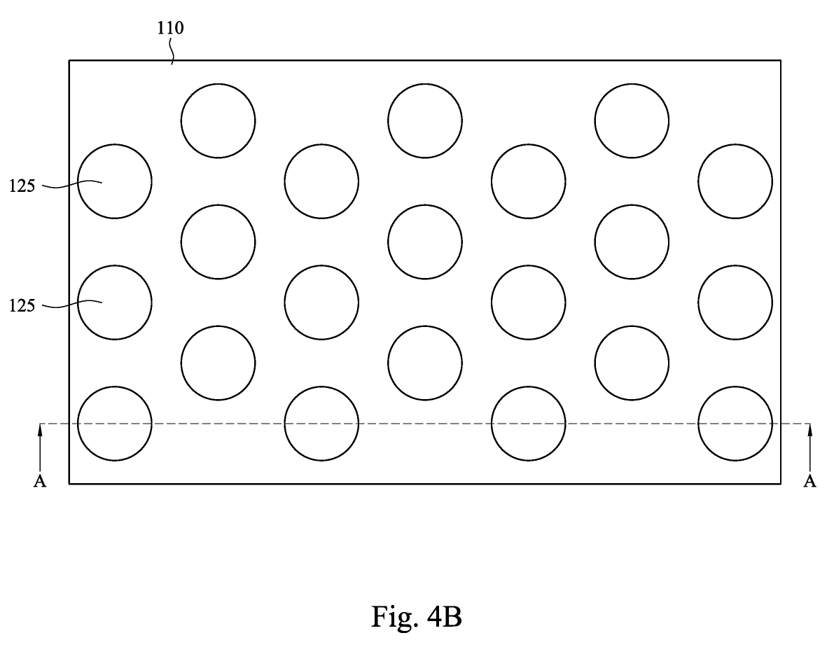

Referring to FIGS. 4A and 4B, a patterned sacrificial layer 125 is then formed on the oxide layer 110 and a portion 112 of the oxide layer 110 is exposed. In some embodiments, the patterned sacrificial layer 125 is substantially aligned with the top electrode 104 of the embedded capacitor 102. The patterned sacrificial layer 125 may be considered as a plurality of dummy pillars disposed on the oxide layer 110 as shown in FIG. 4A. In some embodiments, the plurality of dummy pillars is arranged at intervals. It could be understood that a vertical projection of each of the plurality of dummy pillar on the substrate 100 substantially overlaps a vertical projection of each of the plurality of top electrodes 104 on the substrate 100. That is to say, the arrangement of the dummy pillars is the same with the arrangement of the top electrode 104 of the embedded capacitor 102. Thus, the plurality of dummy pillars is substantially aligned with the top electrodes 104 of the embedded capacitors 102. In some embodiments, each of the plurality of dummy pillars has a round profile in a top view as shown in FIG. 4B.

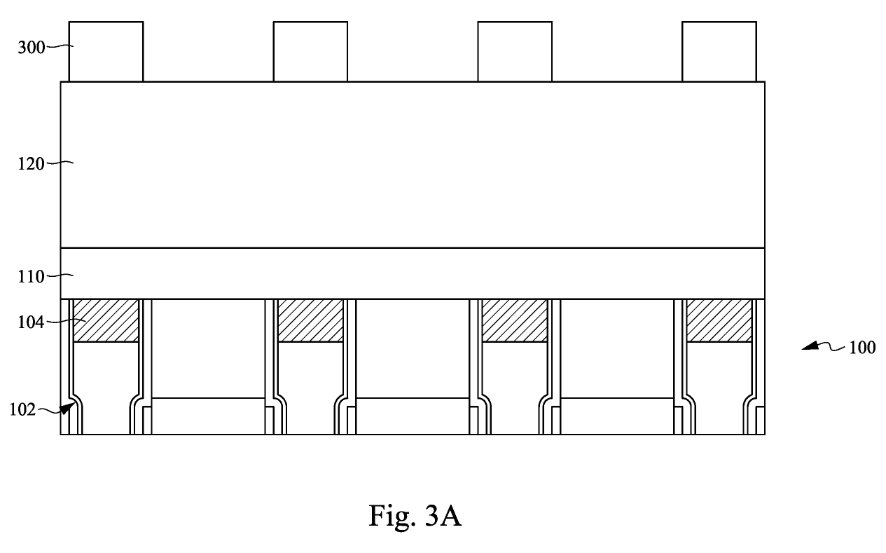

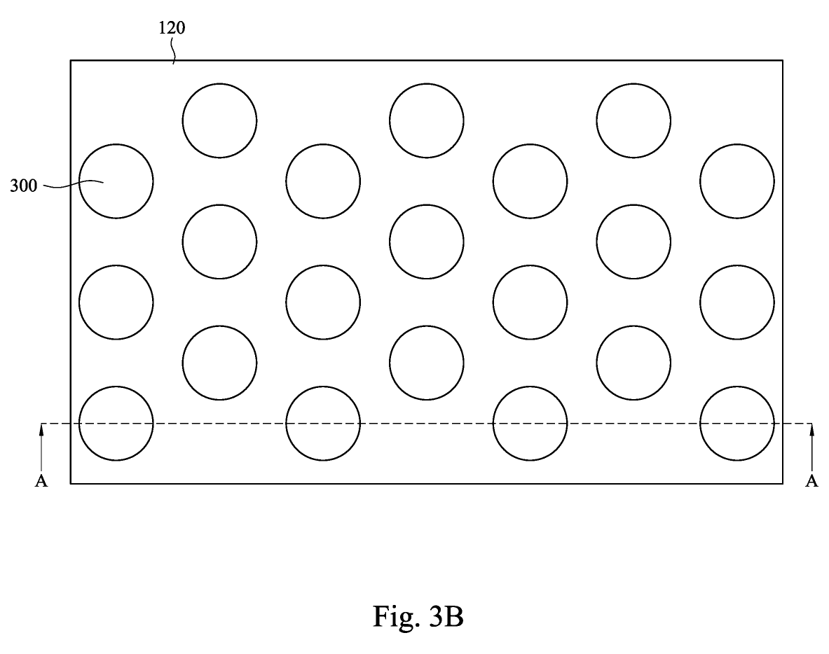

Please refer to FIGS. 2A, 2B, 3A, and FIG. 3B for the formation of the patterned sacrificial layer 125 (also called dummy pillars). The patterned sacrificial layer 125 (or the dummy pillars) may be formed by a photolithography process. The formation of the patterned sacrificial layer 125 includes the following steps. A sacrificial layer 120 is first deposited to cover the substrate 100 as shown in FIG. 2A and FIG. 2B. In some embodiments, the sacrificial layer 120 may include poly silicon or the like. A patterned resist layer 300 is then formed on the sacrificial layer 120 as shown in FIG. 3A and FIG. 3B. The sacrificial layer 120 is patterned by using the patterned resist layer 300 as a mask to form the patterned sacrificial layer 125. The patterned sacrificial layer 125 may be formed by a photolithography process.

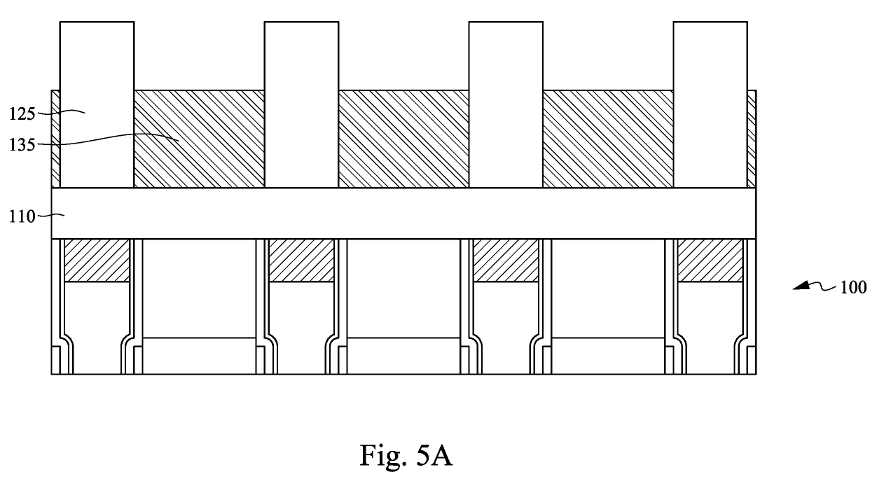

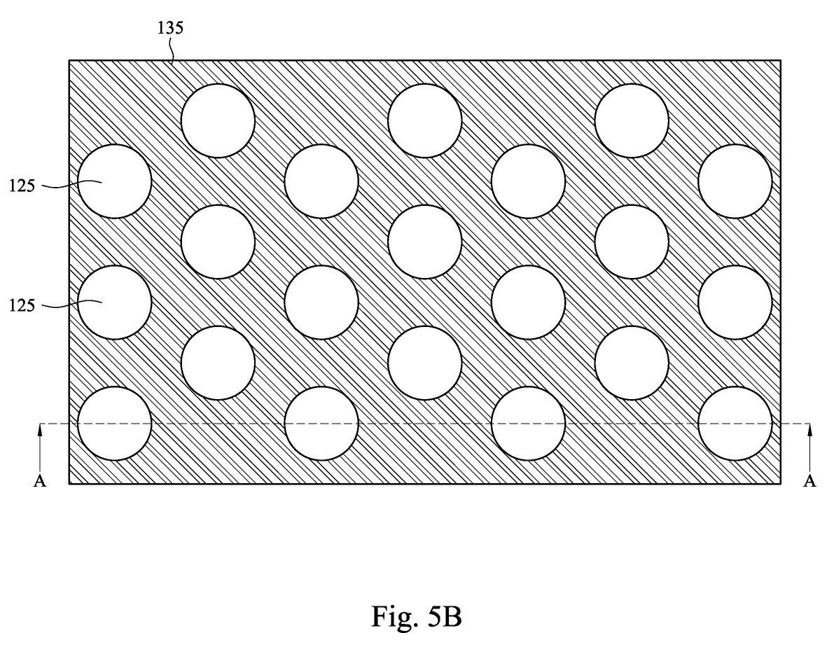

Referring to FIGS. 5A and 5B, a metal layer 135 is formed to cover the portion 112 of the oxide layer 110. The lower portion of the patterned sacrificial layer 125 (or the dummy pillars) is surrounded by the metal layer 135. In some embodiments, a thickness of patterned sacrificial layer 125 is larger than a thickness of the metal layer 135. More specifically, formation of the metal layer 135 includes the following steps. A metal material (not shown) is deposited to cover the portion 112 of the oxide layer 110 and the patterned sacrificial layer 125. In some embodiments, the metal material may include tungsten (W). Then, the metal material is etched back and recessed to form the metal layer 135. It is noted that a height of the metal layer 135 is lower than a height of the patterned sacrificial layer 125.

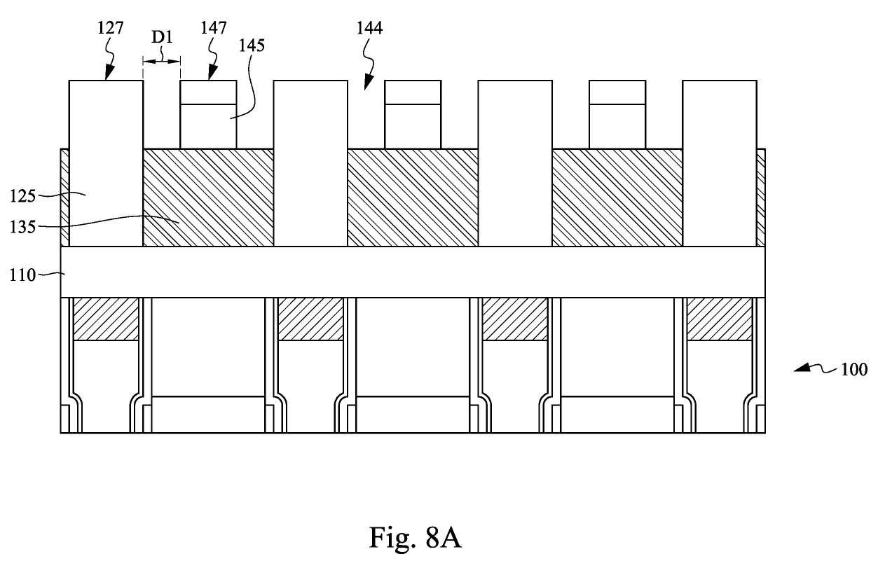

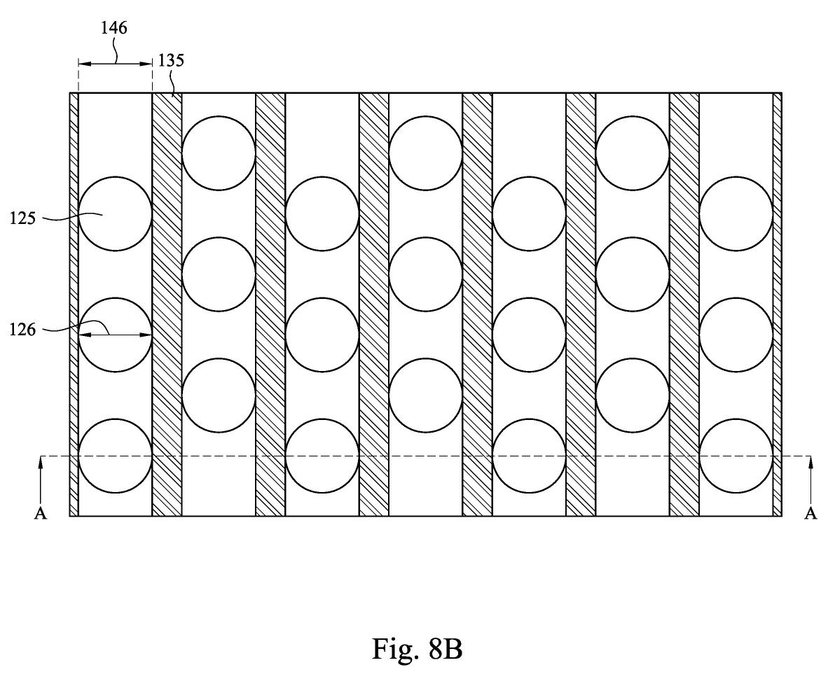

Referring to FIGS. 8A and 8B, a patterned dielectric layer 145 is formed on the metal layer 135. In some embodiments, the patterned dielectric layer 145 is formed between the patterned sacrificial layer125. That is to say that the patterned dielectric layer 145 is formed between two adjacent dummy pillars as shown in FIG. 8A. To be specific, a top surface 147 of the patterned dielectric layer 145 is leveled with a top surface 127 of the patterned sacrificial layer 125. In some embodiments, a width 146 of the patterned dielectric layer 145 is substantially the same as a diameter 126 of each of the plurality of dummy pillars in a top view as shown in FIG. 8B. In some embodiments, the sidewall of the patterned dielectric layer 145 and a sidewall of the closest patterned sacrificial layer 125 are spaced apart from each other. In other words, a first distance D1 exists between the sidewall of the patterned dielectric layer 145 and a sidewall of the closest patterned sacrificial layer 125, and the first distance D1 is greater than 0.

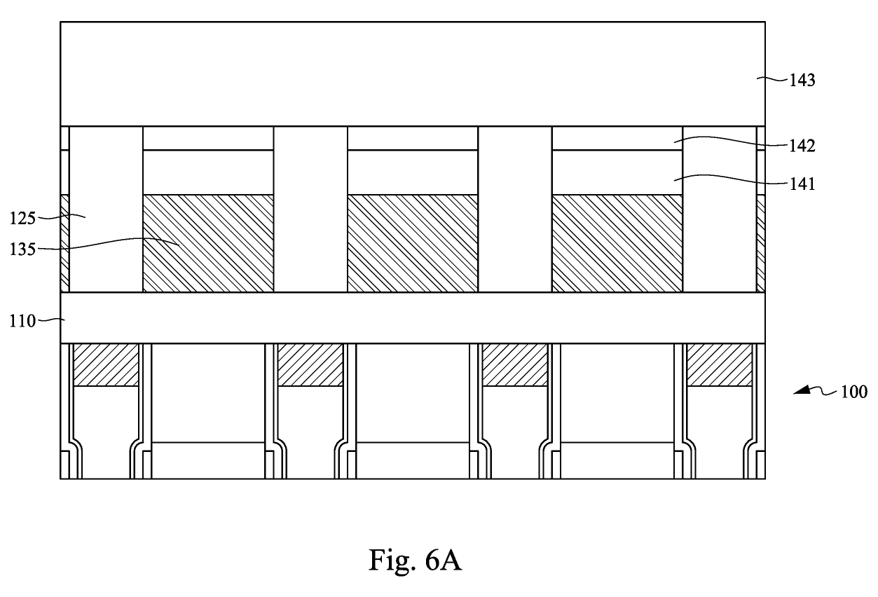

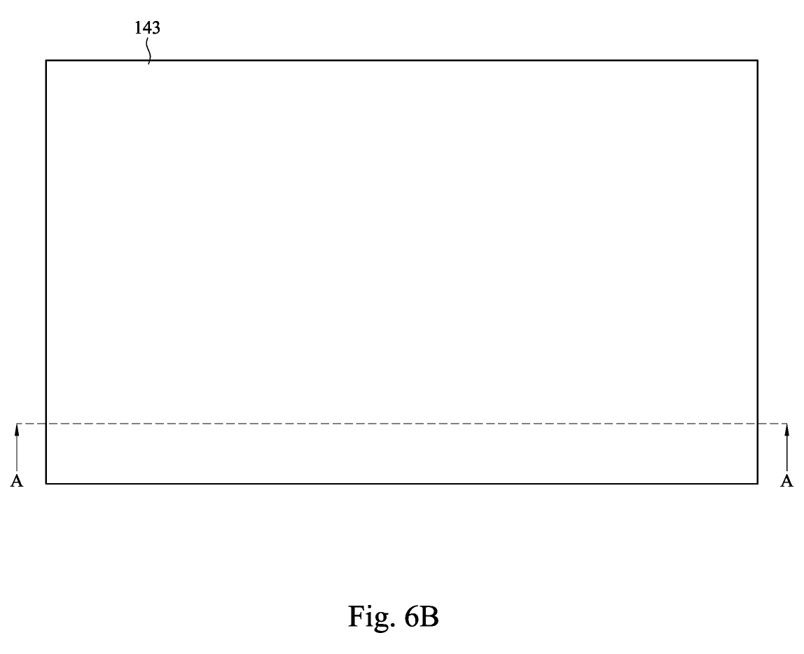

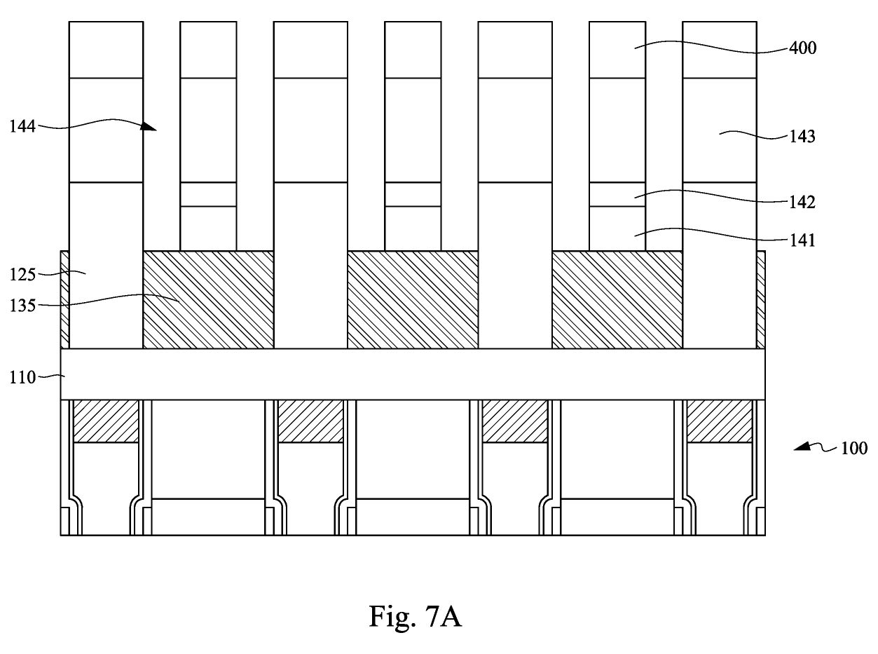

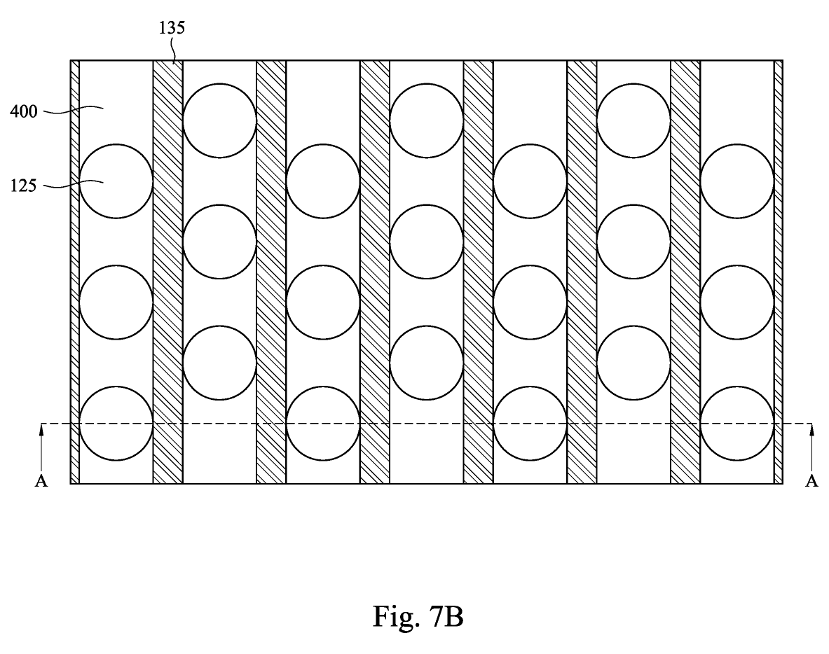

Please refer to FIGS. 6A, 6B, 7A, and FIG. 7B for the formation of the patterned dielectric layer 145. In some embodiments, the formation of the patterned dielectric layer 145 includes the following steps. First of all, an oxide material layer 141 is deposited to cover the metal layer 135 and the patterned sacrificial layer 125. The oxide material layer 141 is subsequently etched back and recessed so that a top surface of the oxide material layer is lower than the top surface of the patterned sacrificial layer. Next, a nitride material layer 142 is deposited to cover the oxide material layer 141 and the patterned sacrificial layer 125. The nitride material layer 142 is subsequently etched back so that a top surface of the nitride material layer 142 is leveled with the top surface of the patterned sacrificial layer 125. A carbon layer 143 is then deposited to cover the nitride material layer 142 and the patterned sacrificial layer 125. A patterned resist layer 400 is formed on the carbon layer 143. The carbon layer 143, the nitride material layer 142, and the oxide material layer 141 are patterned by using the patterned resist layer 400 as a mask. Finally, the patterned resist layer 400 and the patterned carbon layer 143 are removed to form the patterned dielectric layer 145. In some embodiments, the patterned resist layer 400 and the patterned carbon layer 143 are removed by a strip process so that the patterned oxide material layer 141 and the patterned nitride material layer 142 remain on the metal layer 135. In other words, the patterned dielectric layer 145 includes the patterned oxide material layer 141 and the patterned nitride material layer 142.

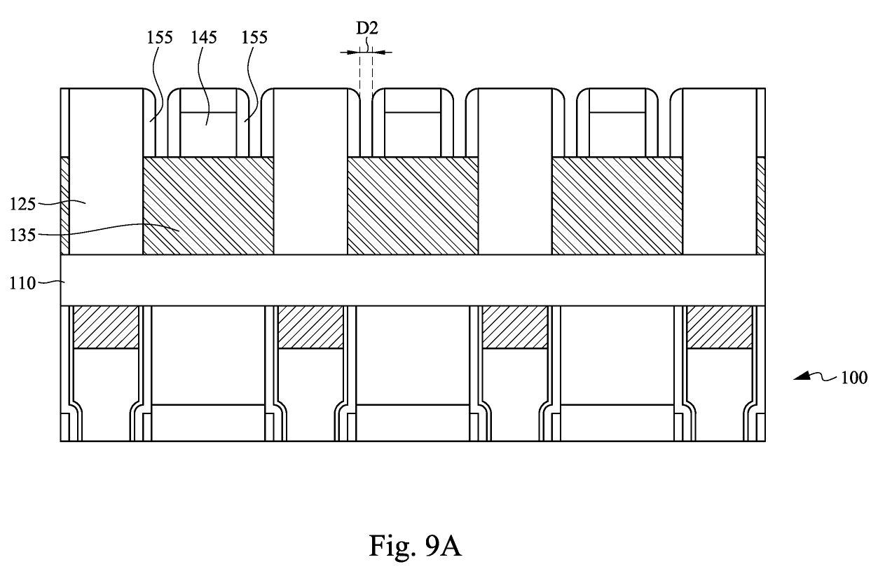

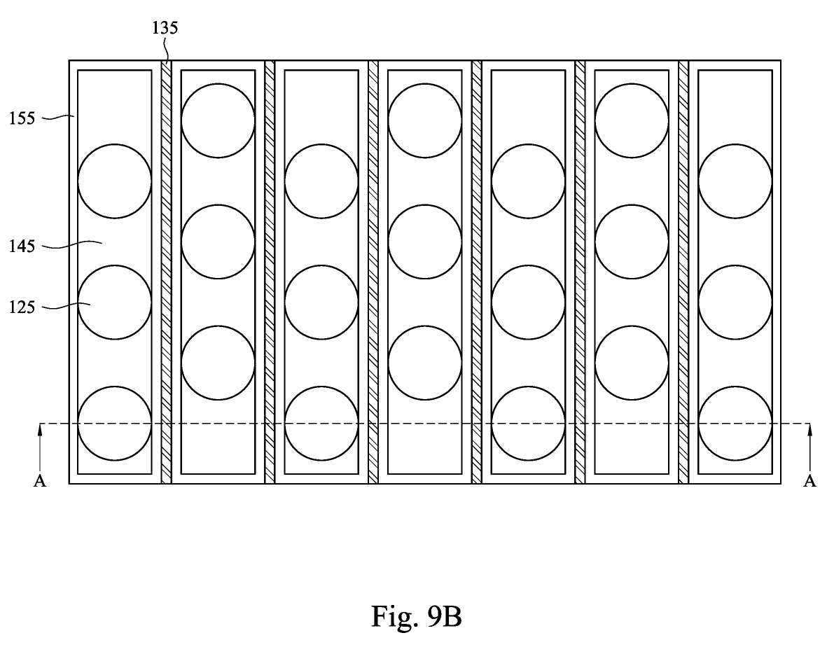

Referring to FIGS. 9A and 9B, a spacer 155 is formed on a sidewall of the patterned dielectric layer 145. More specifically, the spacer 155 is formed on the sidewall of the patterned dielectric layer 145 and an upper portion of each of the plurality of dummy pillars. In some embodiments, an edge of the patterned dielectric layer 145 is surrounded by the spacer 155 in a top view as shown in FIG. 9B. In some embodiments, the spacer 155 on the patterned dielectric layer 145 and the spacer 155 on the closest patterned sacrificial layer 125 are spaced apart from each other. In other words, the second distance D2 is greater than 0 and less than the first distance D1. In some embodiments, spacer 155 may include silicon nitride, SiCO, silicon oxide (SiO₂), or the like.

In some embodiments, the formation of the spacer 155 may include forming an insulating layer (not shown) conformally on the top surface 127 and the sidewall of the patterned sacrificial layer 125, metal layer 135, and the top surface 147 and the sidewalls of the patterned dielectric layer 145. In some embodiments, the insulating layer may be formed by any suitable deposition approaches such as chemical vapor deposition (CVD) techniques, atomic layer deposition (ALD), or physical vapor deposition (PVD) techniques. Then, a portion of the insulating layer on the top surface 127 of the patterned sacrificial layer 125, on the metal layer 135, and on the top surface 147 of the patterned dielectric layer 145 are removed by an anisotropic etching process.

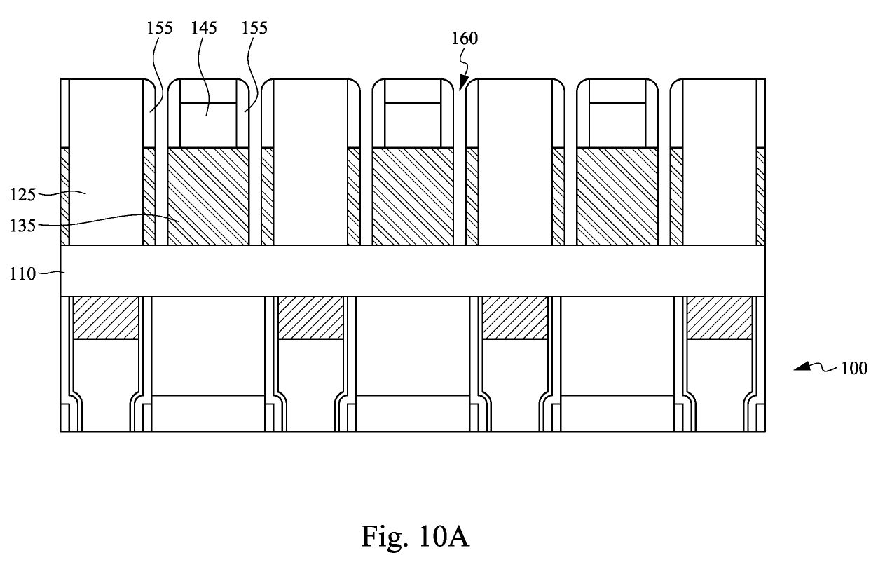

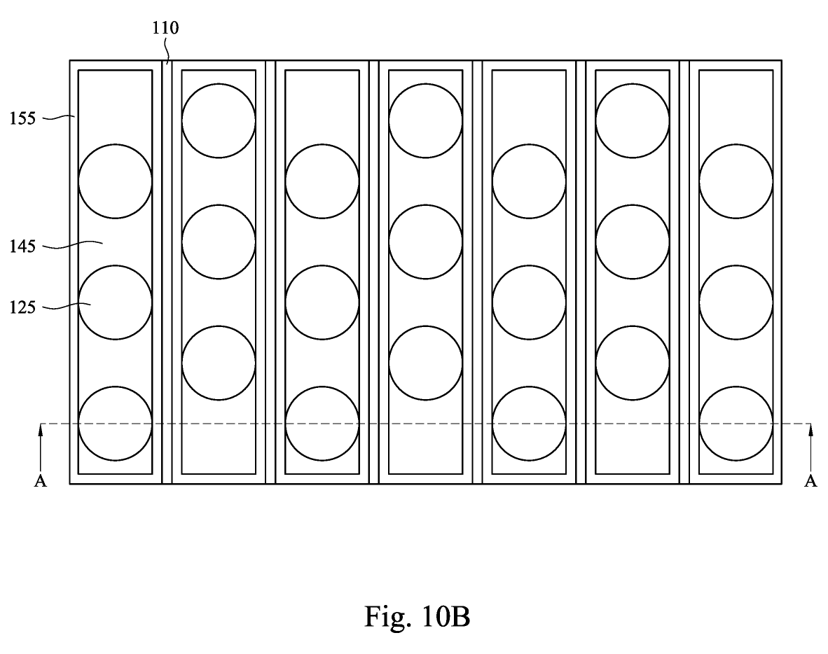

Referring to FIGS. 10A and 10B, the metal layer 135 is patterned by using the spacer 155 and the patterned dielectric layer 145 as a mask to form a gap 160. In some embodiments, a width of the gap 160 is the same with the second distance D2.

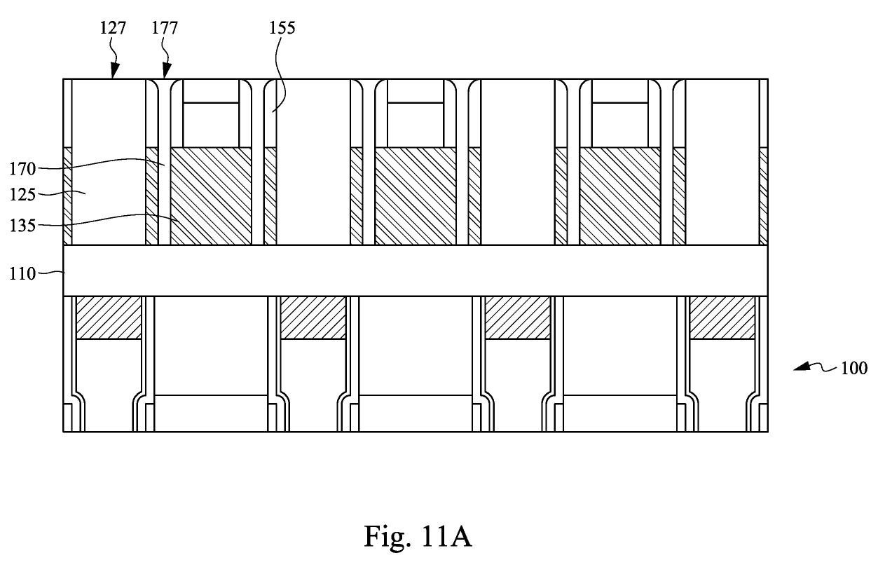

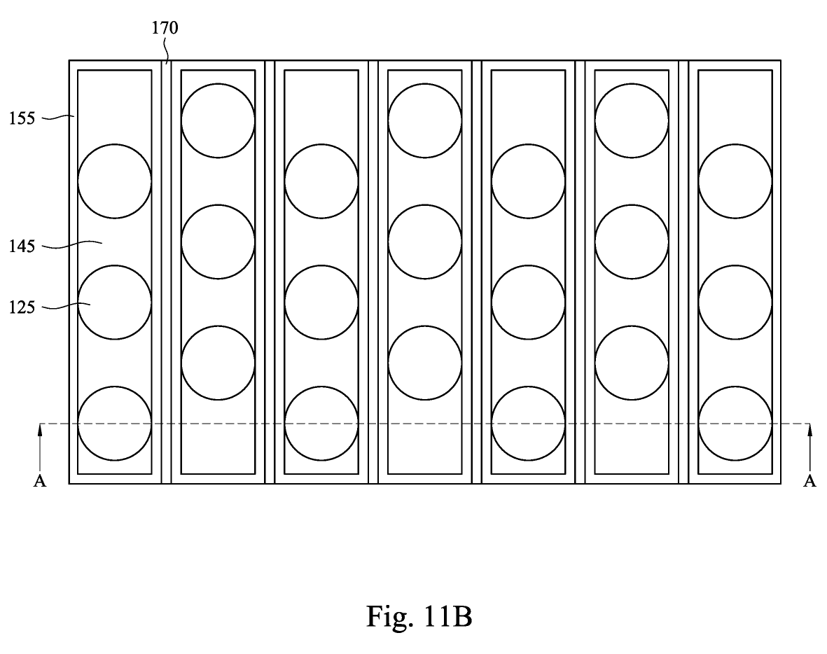

Referring to FIGS. 11A and 11B, a filler 170 is filled up in the gap 160. In some embodiments, the filler 170 may include an oxide. In some embodiments, the filler 170 may include an insulating oxide, such as silicon oxide and the like. The formation of the filler 170 may include the following steps. In some embodiments, the filler 170 may be formed by a single gap-filling process based on a fluid oxide layer. In some other embodiments, the filler 170 may be configured in the form of a combination (e.g., a stacked form) of the fluid oxide layer and the deposition oxide layer. For example, the fluid oxide layer may include a spin-on dielectric (SOD) and the deposition oxide layer may include a high-density plasma (HDP) oxide layer. The filler 170 is then polished by chemical mechanical polishing (CMP) so that the top surface 177 of the filler 170 is leveled with the top surface 127 of the patterned sacrificial layer 125.

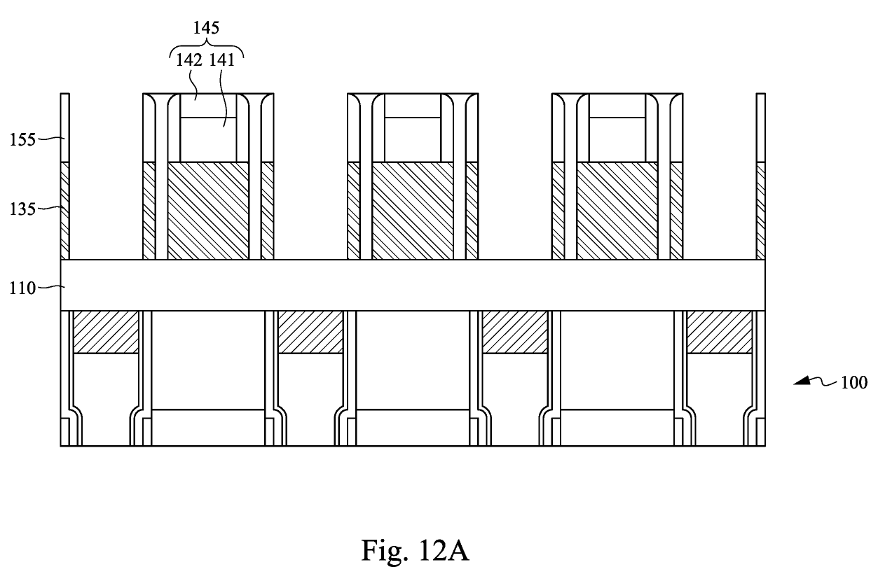

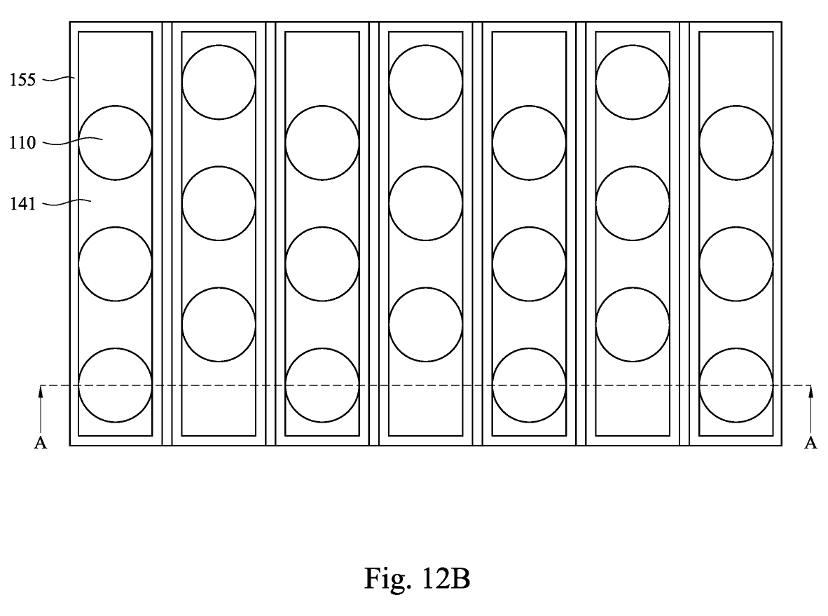

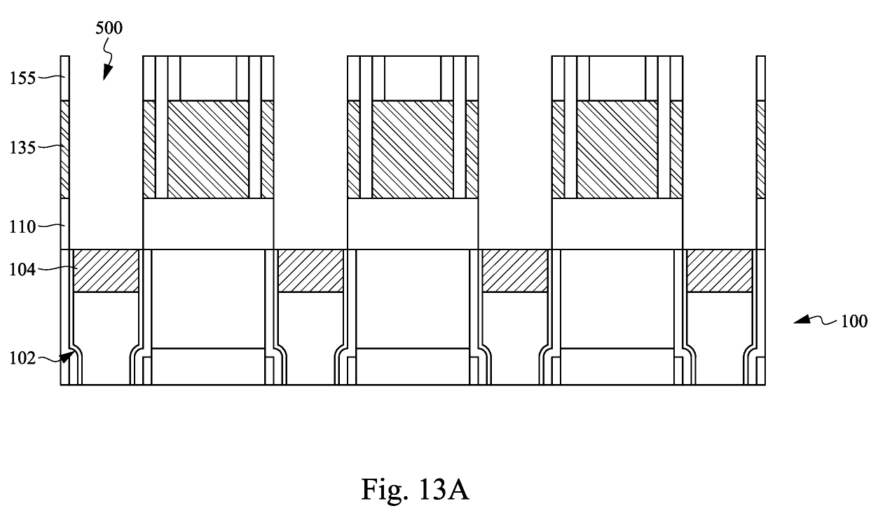

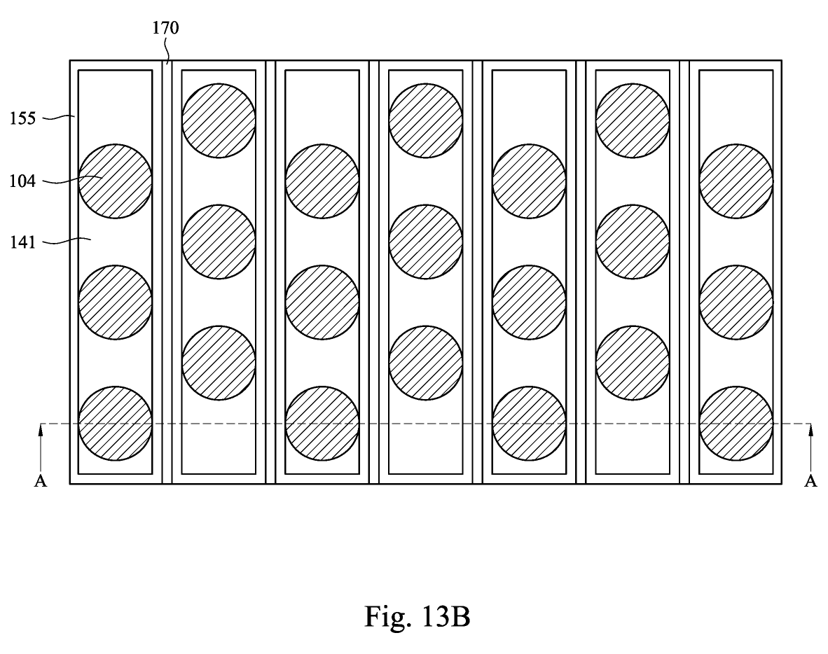

Referring to FIGS. 12A and 12B, the patterned sacrificial layer 125 (the dummy pillars) is removed. Referring to FIGS. 13A and 13B, a portion of the oxide layer 110 is removed to form an opening 500, and the top electrode 104 of the embedded capacitor 120 is exposed from the opening 500. In addition, the patterned nitride material layer 142 of the patterned dielectric layer 145 is further removed. In some embodiments, the removal of the portion of the oxide layer 110 and the patterned nitride material layer 142 may be performed in the same process or in different processes.

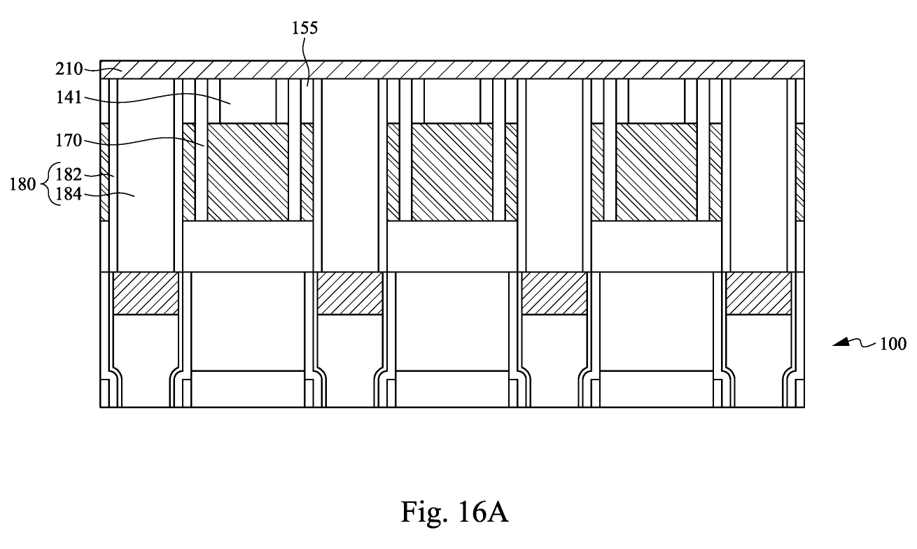

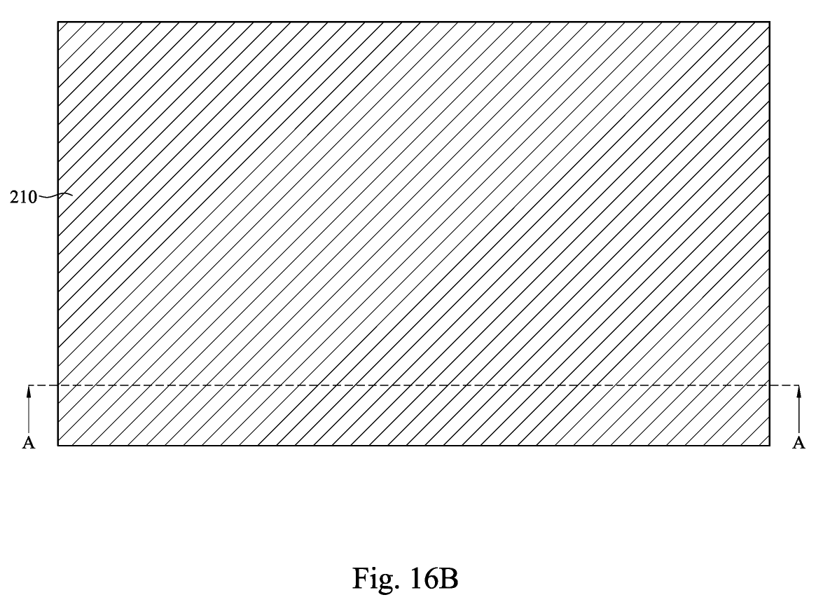

Referring to FIGS. 16A and 16B, a gate structure 180 is formed on the top electrode 104 of the embedded capacitor 120. In some embodiments, the gate structure 180 includes a gate dielectric layer 182 and a gate electrode 184 disposed on the gate dielectric layer 182. In some embodiments, the gate electrode 184 may include indium gallium zinc oxide (IGZO).

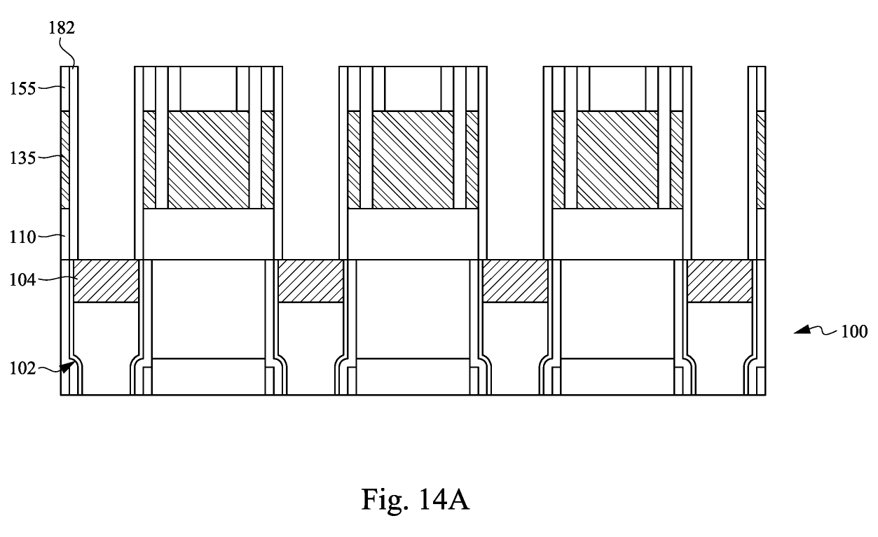

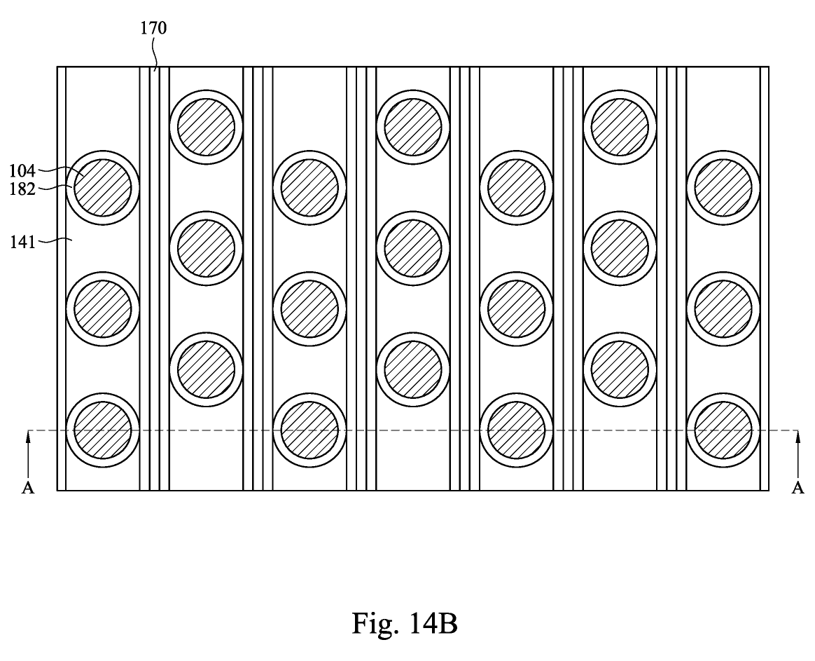

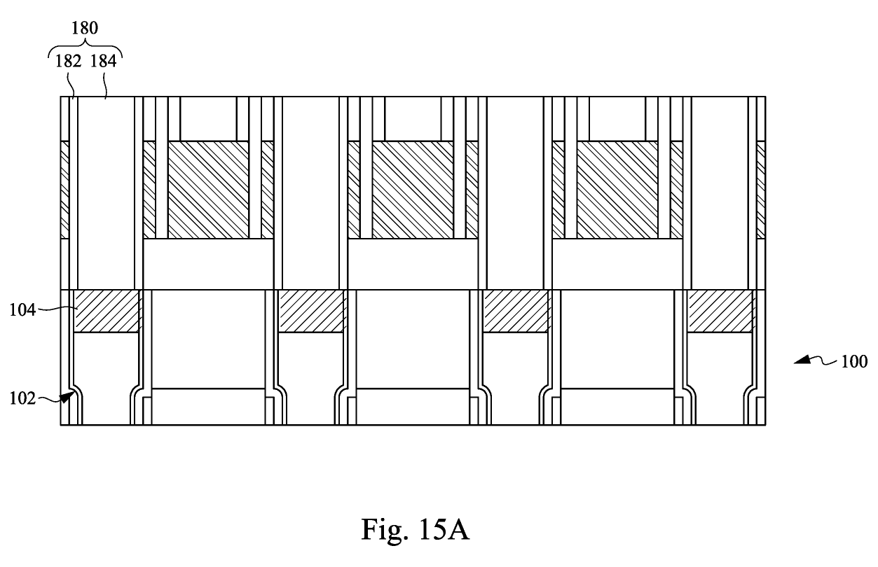

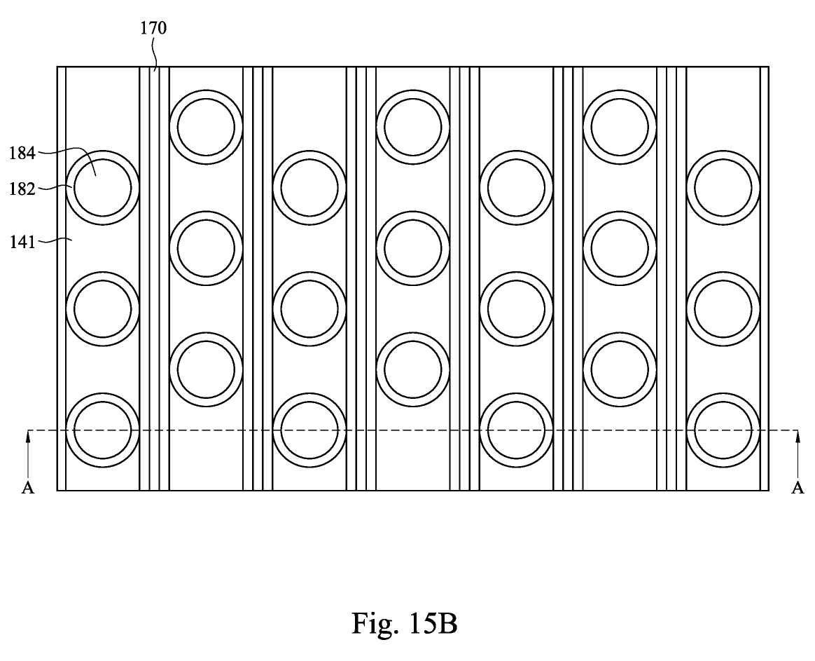

The formation of the gate structure 180 may refer to FIGS. 14A, 14B, 15A, and FIG. 15B. In some embodiments, the gate dielectric layer 182 may be formed by conformally depositing a gate dielectric material (not shown) in the opening 500 and CMP the gate dielectric material, as shown in FIGS. 14A and 14B.

In some embodiments, the gate dielectric material includes one or more layers of a dielectric material, such as silicon oxide, silicon nitride, or high-K dielectric material, other suitable dielectric material, and/or combinations thereof. Examples of high- K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric material may be formed by CVD, ALD or any suitable deposition technique.

Next, the gate electrode 184 may be formed by CVD, ALD, electro-plating, or other suitable deposition technique on the gate dielectric layer 182 in the opening 500, as shown in FIGS. 15A and 15B.

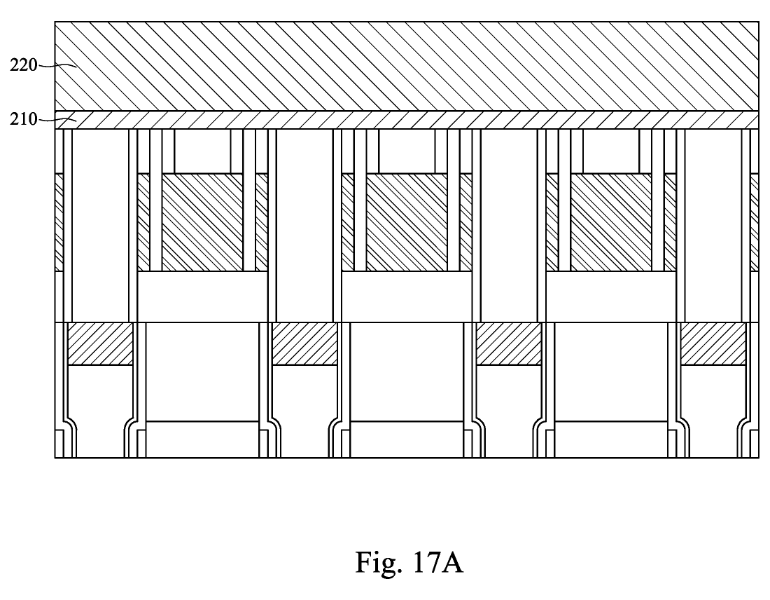

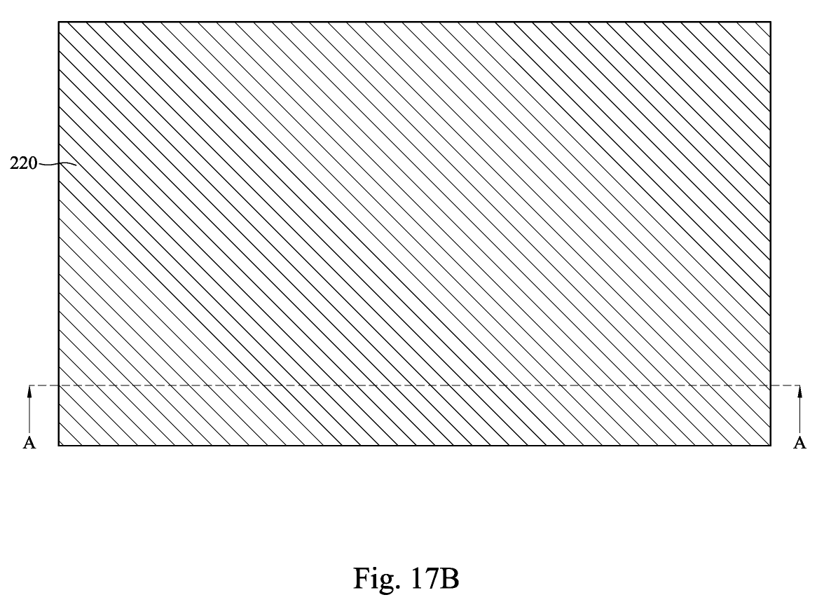

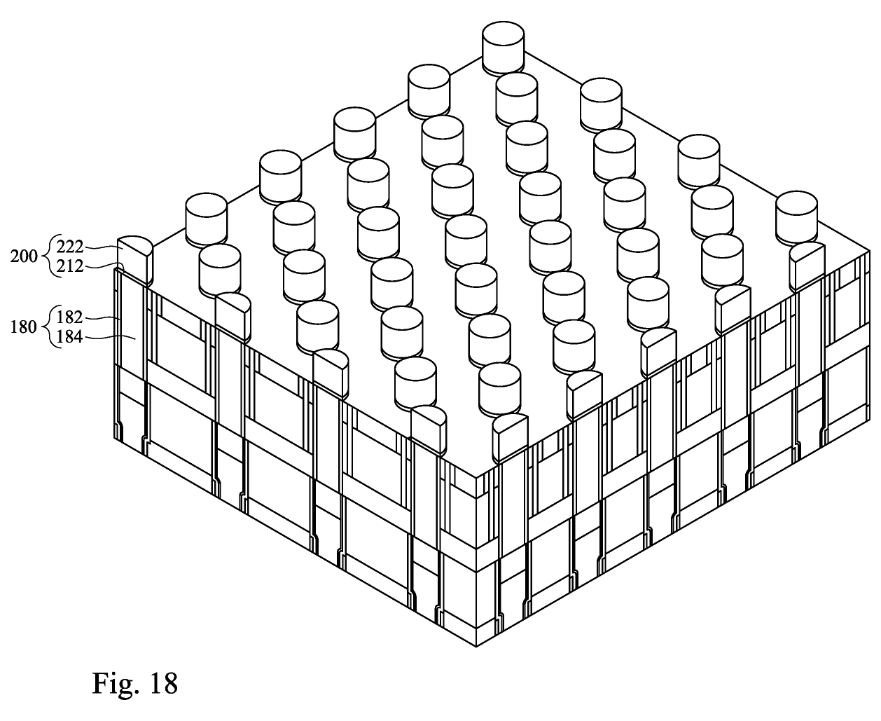

FIG. 18 illustrates a perspective view of a semiconductor structure, in portion, during various fabrication stages, in accordance with some embodiments. Referring to FIG. 18, a landing pad 200 is formed on the gate structure 180. The formation of the landing pad 200 may refer to FIGS. 16A, 16B, 17A, and FIG. 17B. In some embodiments, the landing pad 200 is substantially aligned with the gate structure 180.

Referring to FIGS. 16A and 16B, a first conductive material 210 is formed on the gate structure 180, filler 170, the oxide material layer 141, and the spacer 155. That is to say, the first conductive material 210 completely covers the surface of the structure shown in FIGS. 15A and 15B. In some embodiments, the first conductive material 210 may include indium tin oxide (ITO). In some embodiments, the first conductive material 210 may be deposited by using CVD, ALD, PVD, or other suitable deposition process.

Referring to FIGS. 17A and 17B, a second conductive material 220 is formed on the first conductive material 210. In some embodiments, the second conductive material 220 includes a conductive material. For example, the conductive material is a void-free structure. To achieve the void-free structure, forming the conductive material may include several deposition processes and etching processes. In some embodiments, a deposition/etch-back/deposition (dep/etch/dep) process is employed to deposit the conductive material into a gap (not shown) between two adjacent bit line structures 110. The dep-etch-dep process involves depositing conductive material, followed by etching some of the conductive material back to widen an opening (not shown) of the gap, and followed by re-depositing conductive material. In some embodiments, the second conductive material 220 may include stacked with materials including metal nitride or metal such as tungsten, tungsten nitride, and/or titanium nitride. In some embodiments, the second conductive material 220 may be deposited by using CVD, ALD, PVD, or other suitable deposition process. In some embodiments, a deposition temperature used in the deposition process is in a range of about 280°C to about 320°C. For example, the deposition temperature used in the deposition process can be 280°C, 290°C, 300°C, 310°C, or 320°C. The etching process performed after the deposition process includes using any suitable dry etching processes and/or wet etching processes.

Referring to FIG. 18, at least a portion of the first conductive material 210 and the second conductive material 220 is removed to form a landing pad 200. A mask pattern (not shown) may be formed on the second conductive material 220. Subsequently, the first conductive material 210 and the second conductive material 220 are etched with the mask pattern as an etch mask. In other words, the landing pad 200 includes the patterned first conductive material 212 and the patterned second conductive material 222. Furthermore, the landing pad 200 is formed based on the first conductive material 210 and the second conductive material 220. Thus, the landing pad 200 may include the void-free structure.

The present disclosure provides a novel method of manufacturing a semiconductor structure, which may produce smaller-sized semiconductor device. Furthermore, the novel method of manufacturing a semiconductor structure of the present disclosure may lower the production cost. In addition, the performance of the semiconductor structure may be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor structure, comprising:
receiving a substrate with a top electrode of an embedded capacitor exposed from the substrate;
forming an oxide layer on the substrate;
forming a patterned sacrificial layer on the oxide layer and exposing a portion of the oxide layer;
forming a metal layer to cover the portion of the oxide layer;
forming a patterned dielectric layer on the metal layer, wherein a top surface of the patterned dielectric layer is leveled with a top surface of the patterned sacrificial layer;
forming a spacer on a sidewall of the patterned dielectric layer;
patterning the metal layer by using the spacer and the patterned dielectric layer as a mask to form a gap;
filling the gap with a filler;
removing the patterned sacrificial layer to expose the top electrode of the embedded capacitor; and
forming a gate structure on the top electrode of the embedded capacitor.

2. The method of manufacturing the semiconductor structure of claim 1, wherein the patterned sacrificial layer is substantially aligned with the top electrode of the embedded capacitor.

3. The method of manufacturing the semiconductor structure of claim 1, wherein forming the patterned sacrificial layer comprises:
forming a sacrificial layer to cover the oxide layer;
forming a patterned resist layer on the sacrificial layer; and
patterning the sacrificial layer by using the patterned resist layer as a mask to form the patterned sacrificial layer.

4. The method of manufacturing the semiconductor structure of claim 1, wherein forming the metal layer to cover the portion of the oxide layer comprises:
depositing a metal material covering the portion of the oxide layer and the patterned sacrificial layer;
etching back the metal material; and
recessing the metal material to form the metal layer, wherein a height of the metal layer is lower than a height of the patterned sacrificial layer.

5. The method of manufacturing the semiconductor structure of claim 1, wherein forming the patterned dielectric layer on the metal layer comprises:
depositing an oxide material layer covering the metal layer and the patterned sacrificial layer;
etching back and recessing the oxide material layer so that a top surface of the oxide material layer is lower than the top surface of the patterned sacrificial layer;
depositing a nitride material layer covering the oxide material layer and the patterned sacrificial layer;
etching back the nitride material layer so that a top surface of the nitride material layer is leveled with the top surface of the patterned sacrificial layer;
depositing a carbon layer covering the nitride material layer and the patterned sacrificial layer;
forming a patterned resist layer on the carbon layer;
patterning the carbon layer, the nitride material layer, and the oxide material layer by using the patterned resist layer as a mask; and
removing the patterned resist layer and the patterned carbon layer to form the patterned dielectric layer.

6. The method of manufacturing the semiconductor structure of claim 1, wherein forming the patterned dielectric layer on the metal layer comprises:
forming the patterned dielectric layer between the patterned sacrificial layer, wherein the sidewall of the patterned dielectric layer and a sidewall of the closest patterned sacrificial layer are spaced apart from each other.

7. The method of manufacturing the semiconductor structure of claim 6, wherein the spacer on the patterned dielectric layer and the spacer on the closest patterned sacrificial layer are spaced apart from each other.

8. The method of manufacturing the semiconductor structure of claim 1, wherein the gate structure comprises a gate dielectric layer and a gate electrode disposed on the gate dielectric layer, and the gate electrode comprises indium gallium zinc oxide.

9. The method of manufacturing the semiconductor structure of claim 1, further comprising:
forming a landing pad on the gate structure.

10. A method of manufacturing a semiconductor structure, comprising:
receiving a substrate with a plurality of top electrodes of a plurality of embedded capacitors exposed from the substrate;
forming a plurality of dummy pillars on the plurality of top electrodes of the plurality of embedded capacitors;
depositing a metal layer on the substrate, wherein a plurality of lower portions of the plurality of dummy pillars is surrounded by the metal layer;
forming a patterned dielectric layer on the metal layer and between two adjacent dummy pillars;
forming a spacer on a sidewall of the patterned dielectric layer and an upper portion of each of the plurality of dummy pillars;
patterning the metal layer by using the spacer and the patterned dielectric layer as a mask to form a gap;
filling the gap with a filler;
removing the plurality of dummy pillars to expose the plurality of top electrodes of the plurality of embedded capacitors; and
forming a plurality of gate structures on the plurality of top electrodes of the plurality of embedded capacitors.

11. The method of manufacturing the semiconductor structure of claim 10, further comprising:
forming an oxide layer between the substrate and the plurality of dummy pillars.

12. The method of manufacturing the semiconductor structure of claim 10, wherein the plurality of dummy pillars is arranged at intervals.

13. The method of manufacturing the semiconductor structure of claim 10, wherein each of the plurality of dummy pillars has a round profile in a top view.

14. The method of manufacturing the semiconductor structure of claim 10, wherein a vertical projection of each of the plurality of dummy pillar on the substrate substantially overlaps a vertical projection of each of the plurality of top electrodes on the substrate.

15. The method of manufacturing the semiconductor structure of claim 10, wherein a thickness of each of the plurality of dummy pillars is larger than a thickness of the metal layer.

16. The method of manufacturing the semiconductor structure of claim 10, wherein a width of the patterned dielectric layer is substantially the same as a diameter of each of the plurality of dummy pillars in a top view.

17. The method of manufacturing the semiconductor structure of claim 10, wherein an edge of the patterned dielectric layer is surrounded by the spacer in a top view.

18. The method of manufacturing the semiconductor structure of claim 10, wherein the filler comprises an oxide.

19. The method of manufacturing the semiconductor structure of claim 10, wherein each of the plurality of gate structures comprises a gate dielectric layer and a gate electrode disposed on the gate dielectric layer, and the gate electrode comprises indium gallium zinc oxide.

20. The method of manufacturing the semiconductor structure of claim 10, further comprising:
forming a plurality of landing pads on the plurality of gate structures.
